(19) United States
(12) Patent Application Publication
(10) Pub. No.: US 2020/0168478 A1
(43) Pub. Date: May 28, 2020

(54) CHEMICAL LIQUID SUPPLY APPARATUS AND SEMICONDUCTOR PROCESSING APPARATUS HAVING THE SAME

(71) Applicant: Samsung Electronics Co., Ltd., Suwon-si (KR)

(72) Inventors: Dae Sung Jung, Pohang-si (KR); Sang Yoon Soh, Yongin-si (KR); Jong Min Song, Seoul (KR); Min Ho Kang, Seoul (KR)

(21) Appl. No.: 16/387,779

(22) Filed: Apr. 18, 2019

(30) Foreign Application Priority Data
Nov. 27, 2018 (KR) 10-2018-0148713

(51) Int. Cl. H01L 21/67; H05F 3/00

(52) U.S. Cl. CPC H01L 21/6708; H05F 3/00; H01L 21/67051

(57) ABSTRACT

Provided are a chemical liquid supply apparatus and a semiconductor processing apparatus. The chemical liquid supply apparatus, which supplies a chemical liquid to a process chamber during a semiconductor manufacturing process, may include a chemical liquid supply pipe in which the chemical liquid flows therein and of which a spray end, through which the chemical liquid is sprayed, extends into the process chamber, an external electrode disposed outside the chemical liquid supply pipe, and a power supply module configured to apply power to the external electrode.

### CROSS-REFERENCE TO RELATED APPLICATION

This U.S. non-provisional patent application claims priority under 35 U.S.C. § 119 to and the benefit of Korean Patent Application No. 10-2018-0148713, filed on Nov. 27, 2018, in the Korean Intellectual Property Office (KIPO), the disclosure of which is incorporated herein by reference in its entirety.

### BACKGROUND

### 1. Field

Apparatuses consistent with example embodiments relate to a chemical liquid supply apparatus and a semiconductor processing apparatus having the same.

### 2. Description of Related Art

A chemical liquid supply apparatus is an apparatus which supplies various chemical liquids required in a semiconductor manufacturing process into a process chamber of a semiconductor processing apparatus. For example, in a cleaning process, the chemical liquid supply apparatus supplies a chemical liquid onto a surface of a substrate to remove various contaminants attached to the surface of the substrate or other materials, such as deposited layer materials, which are not contaminants but which may have a considerable effect when cleaning is performed. The cleaning process is an essential process in manufacturing a semiconductor. Contaminants, such as particles, organic contaminants, and metallic contaminants, remaining on the surface of the substrate in the semiconductor manufacturing process can affect characteristics and a production yield of a semiconductor device. The cleaning process may be performed before or after each unit of processing of the semiconductor manufacturing process.

Conventionally, the chemical liquid supply apparatus supplies a chemical liquid stored in a storage container into the process chamber through a supply pipe connected to the storage container. The chemical liquid passing through the pipe may cause an electrostatic phenomenon due to friction with various parts disposed on an inner circumferential surface of the supply pipe or a flow path of the chemical liquid. The electrostatic phenomenon caused by the chemical liquid may adsorb particles onto the surface of the substrate due to electrostatic attraction, thereby lowering a yield of a semiconductor process. In addition, ejection of the charged chemical liquid may apply a direct electrical impact to the substrate. On the other hand, when direct measures are taken inside the pipe to control a level of static electricity of the chemical liquid, there can be problems such as a reaction with the chemical liquid.

### SUMMARY

The example embodiments of the inventive concept are directed to providing a chemical liquid supply apparatus in which a level of static electricity of a chemical liquid flowing in a chemical liquid supply pipe is externally controllable, and a semiconductor processing apparatus having the same.

According to example embodiments, the disclosure is directed to a chemical liquid supply apparatus which supplies a chemical liquid to a process chamber in which a semiconductor manufacturing process is performed, the chemical liquid supply apparatus comprising: a chemical liquid supply pipe in which the chemical liquid flows, the chemical liquid supply pipe including a spray end, through which the chemical liquid is sprayed, configured to extend into the process chamber; an external electrode disposed adjacent to an outer circumferential surface of the chemical liquid supply pipe; and a power supply module configured to apply power to the external electrode.

According to example embodiments, the disclosure is directed to a chemical liquid supply apparatus comprising: a chemical liquid supply pipe comprised of an electrically insulating material and configured to allow a chemical liquid to flow; and an external electrode configured to generate an electric field outside the chemical liquid supply pipe, wherein the electric field generated by the external electrode is applied to the chemical liquid to reduce static electricity caused by friction between the chemical liquid and an inner circumferential surface of the chemical liquid supply pipe.

According to example embodiments, the disclosure is directed to a semiconductor processing apparatus comprising: a process chamber comprising a chamber housing with a box shape having an open upper portion and an inner space and a spin chuck having a spin shaft protruding from a bottom surface of the chamber housing and a spin plate connected to the spin shaft and having an upper surface on which a semiconductor substrate is mounted; a chemical liquid storage tank configured to store a chemical liquid; a chemical liquid supply pump connected to the chemical liquid storage tank; a chemical liquid supply pipe connected to the chemical liquid supply pump in which the chemical liquid flows, the chemical liquid supply pipe including a spray end, through which the chemical liquid is sprayed, configured to extend to be disposed above the spin plate of the process chamber; an external electrode disposed adjacent to an outer circumferential surface of the chemical liquid supply pipe to be adjacent to the spray end; and a power supply module configured to apply power to the external electrode.

### BRIEF DESCRIPTION OF THE DRAWINGS

FIG. 1 is a schematic configuration view illustrating a chemical liquid supply apparatus and a semiconductor processing apparatus including the same, according to an exemplary embodiment of the inventive concept.

FIG. 2A is a partial vertical sectional view illustrating a chemical liquid supply pipe and an external electrode of FIG. 1.

FIG. 2B is a horizontal sectional view taken along line A-A of FIG. 2A.

FIG. 3 is a partial horizontal sectional view illustrating a chemical liquid supply pipe and an external electrode, according to an exemplary embodiment of the inventive concept.

FIG. 4A is a partial vertical sectional view illustrating a chemical liquid supply pipe and an external electrode, according to an exemplary embodiment of the inventive concept.

FIG. 4B is a horizontal sectional view taken along line B-B of FIG. 4A.

FIG. 5A is a partial vertical sectional view illustrating a chemical liquid supply pipe and an external electrode, according to an exemplary embodiment of the inventive concept.

FIG. 5B is a horizontal sectional view taken along line C-C of FIG. 5A.

FIG. 6A is a lateral view illustrating a chemical liquid supply pipe and an external electrode, according to an exemplary embodiment of the inventive concept.

FIG. 6B is a horizontal sectional view taken along line D-D of FIG. 6A.

FIG. 7 is a lateral view illustrating a chemical liquid supply pipe and an external electrode, according to an exemplary embodiment of the inventive concept.

FIG. 8A is a vertical sectional view illustrating a chemical liquid supply pipe, an external electrode, and a protective layer, according to an exemplary embodiment of the inventive concept.

FIG. 8B is a horizontal sectional view taken along line E-E of FIG. 8A.

FIG. 9 is a schematic configuration view illustrating a chemical liquid supply pipe, an external electrode, and a power supply module, according to an exemplary embodiment of the inventive concept.

FIG. 10 is a schematic configuration view illustrating a chemical liquid supply apparatus and a semiconductor processing apparatus including the same, according to an exemplary embodiment of the inventive concept.

FIG. 11 is a flow chart illustrating a method of manufacturing a semiconductor device, according to example embodiments.

### DETAILED DESCRIPTION OF EXEMPLARY EMBODIMENTS

Hereinafter, a chemical liquid supply apparatus and a semiconductor processing apparatus including the same, according to exemplary embodiments of will be described.

First, a chemical liquid supply apparatus and a semiconductor processing apparatus according to an exemplary embodiment of the inventive concept will be described.

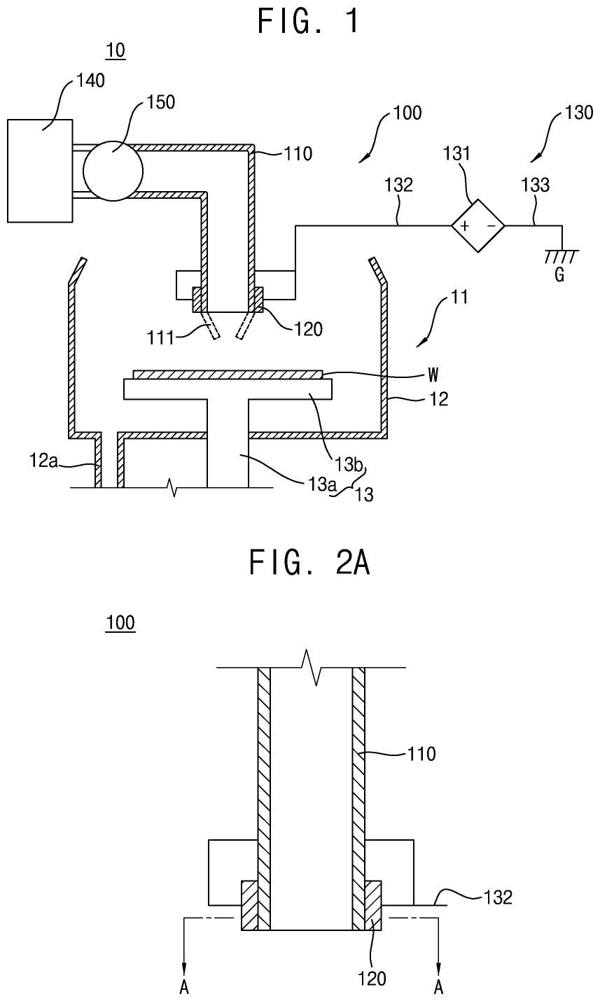

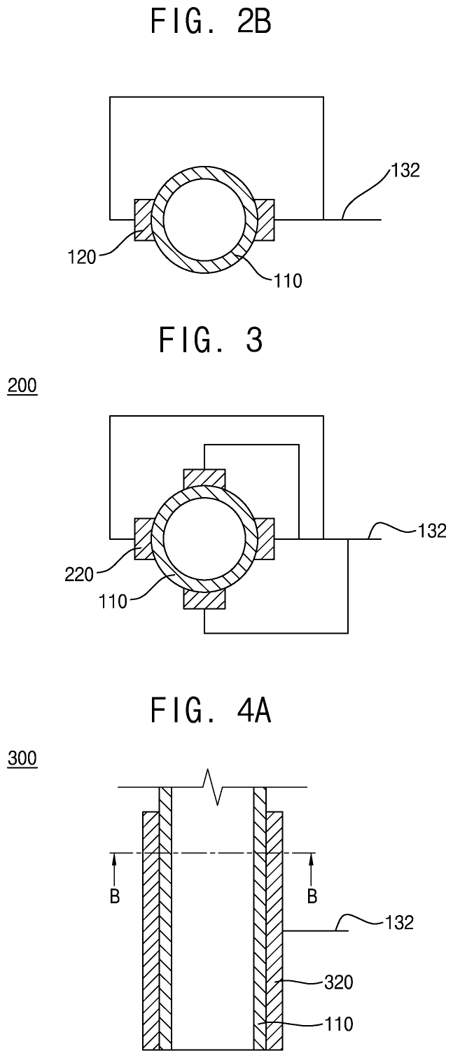

FIG. 1 is a schematic configuration view illustrating a chemical liquid supply apparatus and a semiconductor processing apparatus including the same, according to an exemplary embodiment of the inventive concept. FIG. 2A is a partial vertical sectional view illustrating a chemical liquid supply pipe and an external electrode of FIG. 1. FIG. 2B is a horizontal sectional view taken along line A-A of FIG. 2A.

Referring to FIGS. 1, 2A, and 2B, a chemical liquid supply apparatus 100 according to the exemplary embodiment of the inventive concept includes a chemical liquid supply pipe 110, an external electrode 120, and a power supply module 130. The chemical liquid supply apparatus 100 may further include a chemical liquid storage tank 140 and a chemical liquid supply pump 150. The chemical liquid supply apparatus 100 may constitute a semiconductor processing apparatus 10 together with a process chamber 11 in which a semiconductor manufacturing process is performed. For example, the semiconductor processing apparatus 10 may include the process chamber 11 and the chemical liquid supply apparatus 100.

Referring to FIG. 1, in the chemical liquid supply apparatus 100, the chemical liquid supply pipe 110 extends to be disposed above a semiconductor substrate W which is mounted on a spin chuck of the process chamber 11. The chemical liquid supply apparatus 100 supplies a chemical liquid to a surface of the semiconductor substrate W during a semiconductor manufacturing process. For example, the chemical liquid supply apparatus 100 supplies a chemical liquid to an upper surface of the semiconductor substrate W. The semiconductor manufacturing process may include various processes such as a cleaning process and an etching process, and the chemical liquid supply apparatus 100 may be used in the cleaning process and the etching process. For example, the cleaning process is a process of removing impurities remaining on the surface of the semiconductor substrate using a cleaning liquid such as deionized water or an organic solvent. In addition, the etching process is a process of removing an unnecessary region of a thin film formed on the semiconductor substrate by using an etchant. After the thin film is removed in the etching process, a cleaning process of cleaning the etchant using a cleaning liquid may be additionally performed. The process chamber may include various chambers such as an etching chamber and a cleaning chamber. The chemical liquid may be a chemical liquid for a wet process of the semiconductor substrate, such as an etchant, a cleaning liquid, or a cleaning solution. For example, the chemical liquid may be standard cleaning-1 (SC-1) including HF or SF₆ or an ammonium hydroxide aqueous solution in which ammonium hydroxide (NH₄OH) is dissolved in pure water. The chemical liquid may be an organic solvent such as methanol, ethanol, 2-propanol, n-butanol, isopropyl alcohol, ethylglycol, propylglycol, butylglycol, ethyldiglycol, butyldiglycol, n-pentane, acetone, ethyl acetate, methyl ethyl ketone, n-heptane, toluene, methyl isobutyl ketone, isobutyl acetate, n-butyl acetate, sec-butyl alcohol, 2-ethoxyethanol, methyl n-amyl ketone, 2-ethoxy ethyl acetate, n-decane, 2-butoxyethanol, or isoprene.

In the semiconductor manufacturing process, it is important to remove particles that can greatly affect the quality and yield of a semiconductor device. In addition, the particles may be adsorbed onto the semiconductor substrate, and a degree of the adsorption may be increased according to a level of static electricity charged in the chemical liquid. In this case, when a size of the particles is small, it is difficult to remove the particles using a chemical filter. Therefore, in order to reduce the degree of the adsorption onto the semiconductor substrate, it is necessary to reduce or remove static electricity of the chemical liquid. In addition, in the semiconductor manufacturing process, the semiconductor device may be damaged when an arcing phenomenon or other sudden charge transfer phenomenon due to static electricity occurs on the surface of the semiconductor substrate. Therefore, it is helpful to control a level of the static electricity of the chemical liquid supplied to the semiconductor substrate in order to secure a higher quality and yield of the semiconductor device.

Referring to FIG. 1, the semiconductor processing apparatus 10 may include the process chamber 11 and the chemical liquid supply apparatus 100. The process chamber 11 may be a cleaning chamber or an etching chamber. For example, referring to FIG. 1, the process chamber 11 may include a chamber housing 12 and a spin chuck 13. The chamber housing 12 may be formed to have a box shape having an open upper portion and an inner space with a certain volume. The spin chuck 13 configured to fix and rotate the semiconductor substrate W is disposed on a bottom surface of the chamber housing 12. For example, the spin chuck 13 may be disposed in the inner space at a lower portion of the chamber housing 12. In addition, a discharge pipe 12a through which a used cleaning liquid is discharged to the outside is formed in the bottom surface of the chamber housing 12. The spin chuck 13 includes a spin shaft 13a protruding from the bottom surface of the chamber housing 12 and a spin plate 13b connected to an upper portion of the spin shaft 13a and having an upper surface to which the semiconductor substrate W is fixed. The semiconductor substrate W may be rotated by fixing the semiconductor substrate W to the spin plate 13b and then rotating the spin shaft 13a. The chemical liquid supply pipe 110 configured to supply a cleaning liquid is disposed above the chamber housing 12 to extend in an upper portion of the chamber housing 12. The chemical liquid supply pipe 110 supplies the cleaning liquid to an upper surface of the rotating semiconductor substrate W to remove contaminants on the semiconductor substrate W.

In the chemical liquid supply apparatus 100, the external electrode 120 is disposed outside the chemical liquid supply pipe 110, and the power supply module 130 is electrically connected to the external electrode 120. In the chemical liquid supply apparatus 100, the power supply module 130 may supply power to the external electrode 120 to generate an electric field outside the chemical liquid supply pipe 110. Therefore, the chemical liquid supply apparatus 100 may reduce a level of static electricity by allowing the static electricity to flow, wherein the static electricity is caused by friction between the chemical liquid and an inner circumferential surface of the chemical liquid supply pipe 110 or is caused by an action due to other various flows. For example, the friction of the chemical liquid may cause static electrification in which a positive charge and a negative charge are arranged inside the chemical liquid. The electric field generated due to the external electrode 120 may change an arrangement of the positive charge and the negative charge in the chemical liquid to adjust or reduce an amount of static electrification.

The chemical liquid supply pipe 110 is formed as a pipe structure having a certain length. The chemical liquid supply pipe 110 has an inflow end connected to the chemical liquid supply pump 150 and a spray end extending into the process chamber 11. Therefore, the chemical liquid supply pipe 110 may be formed to have a certain length according to a distance between the chemical liquid supply pump 150 and the process chamber 11. The chemical liquid supply pipe 110 may supply various chemical liquids at a flow rate required according to characteristics of the semiconductor manufacturing process. Accordingly, the chemical liquid supply pipe 110 may be formed as a pipe having an appropriate inner diameter (e.g., the diameter of the inside circumferential surface). The chemical liquid supply pipe 110 may be vertically disposed inside the process chamber 11 and may be obliquely disposed to supply the chemical liquid in a downward direction. The chemical liquid supply pipe 110 may extend to a position where the spray end thereof is spaced a certain height from an upper portion of the spin chuck 13 of the process chamber 11. The chemical liquid supply pipe 110 supplies a chemical liquid supplied from the chemical liquid storage tank 140 by the chemical liquid supply pump 150 to the surface of the semiconductor substrate W.

Meanwhile, the chemical liquid supply pipe 110 may additionally include a spray nozzle 111 formed at the spray end. The spray nozzle 111 may reduce a diameter of the spray end of the chemical liquid supply pipe 110 to increase pressure of the supplied chemical liquid.

The chemical liquid supply pipe 110 may be made of a material having chemical resistance to the chemical liquid flowing therein and having electric insulation. For example, the chemical liquid supply pipe 110 may be made of a fluoride resin such as polyvinylidenefluoride (PVDF), perfluoroalkoxy (PFA), or polytetrafluoroethylene (PTFE). In addition, the chemical liquid supply pipe 110 may be made of styrene resin, polyamide resin, or polyetheretherketone (PEEK) resin.

The external electrode 120 may be formed in a plate or block shape having a certain area. The external electrode 120 is formed to have an area capable of supplying desired charges to the outside of the chemical liquid supply pipe 110. The external electrode 120 may be formed to have an appropriate width and length according to a diameter of the chemical liquid supply pipe 110 to which the external electrode 120 is attached. Here, the width means a distance in a direction perpendicular to a central axis direction of the chemical liquid supply pipe 110, and the length means a distance in a direction parallel to the central axis direction. The external electrode 120 is disposed outside the chemical liquid supply pipe 110. One or two external electrodes 120 may be formed. When one external electrode 120 is formed, the external electrode 120 may be coupled to a certain position on an outer circumferential surface of the chemical liquid supply pipe 110. When two external electrodes 120 are formed, the external electrodes 120 may be coupled to the outer circumferential surface of the chemical liquid supply pipe 110 so as to be spaced apart from each other in a circumferential direction of the chemical liquid supply pipe 110. In addition, each of the external electrodes 120 may be formed to have a width less than half of the length of a perimeter of the outer circumferential surface of the chemical liquid supply pipe 110. The external electrode 120 may be formed such that a length thereof is less than or equal to a width thereof. The external electrodes 120 may be disposed symmetrically with respect to a central axis of the chemical liquid supply pipe 110. Herein, the width of the external electrodes 120 is measured in the circumferential direction at an outer surface of the chemical liquid supply pipe 110, and the length of the external electrodes 120 is measured in a direction parallel to the central axis of the chemical liquid supply pipe 110. For example, a width of an external electrode 120 may be the distance of an inside surface (e.g., surface facing the chemical liquid supply pipe 110) of the external electrode 120 measured in the circumferential direction, and a length of external electrode 120 may be the distance of the inside surface of the external electrode 120 measured in a direction parallel to the axis of the chemical liquid supply pipe 110. The circumferential direction and the direction parallel to the axis of the chemical liquid supply pipe 110 may be perpendicular to one another.

The external electrode 120 may be disposed adjacent to the spray end of the chemical liquid supply pipe 110. In addition, the external electrode 120 may be formed such that a lower end thereof is aligned with the spray end of the chemical liquid supply pipe 110. Here, the lower end of the external electrode 120 means an end located in a lower direction in FIG. 1. When the lower end of the external electrode 120 is aligned with the spray end of the chemical liquid supply pipe 110, a chemical liquid may be exposed to an electric field before the chemical liquid is sprayed. Static electricity may be effectively removed by applying an electric field until the chemical liquid is sprayed from the chemical liquid supply pipe 110.

The external electrode 120 may be adjacent to an outer circumferential surface of the chemical liquid supply pipe 110. For example, the external electrode 120 may be in direct contact with the outer circumferential surface of the chemical liquid supply pipe 110 or may be disposed to be spaced apart from the outer circumferential surface. The external electrode 120 may be coupled to the outer circumferential surface of the chemical liquid supply pipe 110 through a separate adhesive. In this case, when the adhesive is entirely applied, the external electrode 120 may be spaced apart from the outer circumferential surface of the chemical liquid supply pipe 110. In addition, when the adhesive is partially applied, the external electrode 120 may be partially in direct contact with the outer circumferential surface of the chemical liquid supply pipe 110. Furthermore, the external electrode 120 may be coupled to the outer circumferential surface of the chemical liquid supply pipe 110 with a bolt. In this case, the external electrode 120 may be in direct contact with the outer circumferential surface of the chemical liquid supply pipe 110. Here, the bolt may be coupled so as to not pass through the chemical liquid supply pipe 110. The external electrode 120 may generate an electric field outside of the chemical liquid supply pipe 110, thereby reducing or removing static electricity caused by friction between the chemical liquid and the inner circumferential surface of the chemical liquid supply pipe 110. It will be understood that the term “contact,” as used herein, refers to a direct connection (i.e., touching) unless the context indicates otherwise.

The external electrode 120 may be made of a conductive metal such as copper, nickel, or aluminum. In addition, the external electrode 120 may be made of a composite material in which carbon and a resin are mixed. For example, the external electrode 120 may be made of PVDF including carbon, PEEK including carbon, PFA including carbon, or PTFE including carbon.

The power supply module 130 may be electrically connected to the external electrode 120 and may apply positive power or negative power. When a positive terminal of the power supply module 130 is connected to the external electrode 120, a negative terminal of the power supply module 130 may be connected to a ground. The power supply module 130 may supply a voltage of thousands of volts (kV). For example, the power supply module 130 may apply a voltage of several kV to the external electrode 120. The power supply module 130 may supply direct current (DC) power or alternating current (AC) power.

The power supply module 130 may include a power source 131, a power line 132, and a ground line 133. The power supply module 130 may be electrically connected to the external electrode 120. The power source 131 may apply a positive DC voltage or a negative DC voltage to the external electrode 120. In addition, the power source 131 may apply an AC voltage to the external electrode 120. The power line 132 electrically connects the power source 131 and the external electrode 120. The ground line 133 connects the power source 131 to a ground G.

The chemical liquid storage tank 140 may be formed as a general tank capable of storing a chemical liquid. The chemical liquid storage tank 140 may be made of a resin material having chemical resistance to a chemical liquid. For example, the chemical liquid storage tank 140 may be made of a fluorine resin such as PVDF, PFA, or PTFE. In addition, the chemical liquid storage tank 140 may be made of styrene resin, polyamide resin, or PEEK resin. Furthermore, the chemical liquid storage tank 140 may be made of a metal material having corrosion resistance. For example, the chemical liquid storage tank 140 may be made of stainless steel.

The chemical liquid supply pump 150 may be formed as a general pump configured to supply a chemical liquid. The chemical liquid supply pump 150 is connected between the chemical liquid storage tank 140 and the chemical liquid supply pipe 110. The chemical liquid supply pump 150 supplies the chemical liquid stored in the chemical liquid storage tank 140 to the chemical liquid supply pipe 110.

Next, a chemical liquid supply apparatus according to an exemplary embodiment of the inventive concept will be described.

FIG. 3 is a partial horizontal sectional view illustrating a chemical liquid supply pipe and an external electrode according to an exemplary embodiment of the inventive concept.

Referring to FIGS. 1 and 3, a chemical liquid supply apparatus 200 according to the exemplary embodiment of the inventive concept includes a chemical liquid supply pipe 110, an external electrode 220, and a power supply module 130, including power line 132. A configuration of the external electrode 220 of the chemical liquid supply apparatus 200 is different from that of the external electrode 120 of the chemical liquid supply apparatus 100 shown in FIGS. 1, 2A, and 2B. Therefore, hereinafter, the chemical liquid supply apparatus 200 will be described by focusing on the external electrode 220 different from the external electrode 120. In addition, in the chemical liquid supply apparatus 200, components which are identical or similar to those of the chemical liquid supply apparatus 100 shown in FIGS. 1, 2A, and 2B, are denoted by the same reference numerals, and detailed descriptions thereof will be omitted. On the other hand, components different from those of the chemical liquid supply apparatus 200 shown in FIGS. 1, 2A, and 2B are denoted by different reference numerals, and differences thereof will be mainly described.

Four external electrodes 220 may be formed and may be spaced apart from each other in a circumferential direction on an outer circumferential surface of the chemical liquid supply pipe 110. In addition, each of the external electrodes 220 may be formed to have a width less than a quarter of the length of a perimeter of the outer circumferential surface of the chemical liquid supply pipe 110. The external electrodes 220 may be spaced the same interval from each other in the circumferential direction of the chemical liquid supply pipe 110. For example, the external electrodes 220 may be spaced equidistant from one another on the outside surface of the chemical liquid supply pipe 110. Since the external electrodes 220 are disposed at the same interval on the entire outer circumferential surface of the chemical liquid supply pipe 110, the external electrodes 220 may more uniformly generate an electric field outside the chemical liquid supply pipe 110.

Next, a chemical liquid supply apparatus according to an exemplary embodiment of the inventive concept will be described.

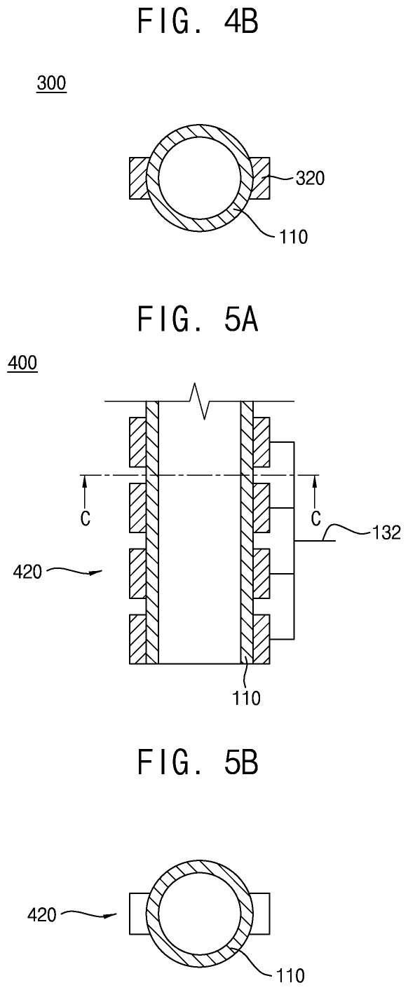

FIG. 4A is a partial vertical sectional view illustrating a chemical liquid supply pipe and an external electrode according to an exemplary embodiment of the inventive concept. FIG. 4B is a horizontal sectional view taken along line B-B of FIG. 4A.

Referring to FIGS. 1, 4A, and 4B, a chemical liquid supply apparatus 300 according to the exemplary embodiment of the inventive concept includes a chemical liquid supply pipe 110, an external electrode 320, and a power supply module 130, including power line 132.

The external electrode 320 may be formed to have a shape of which a length thereof is greater than a width thereof. For example, the external electrode 320 may be formed in a bar or band shape. In addition, the external electrode 320 may be formed to have a length greater than a diameter or a perimeter length of the chemical liquid supply pipe 110. Furthermore, the external electrode 320 may be formed to have a sufficiently long length according to a level of static electricity generated in a chemical liquid. The external electrode 320 may be formed to have a length that corresponds to a length of the chemical liquid supply pipe 110.

The external electrode 320 may be disposed such that a length thereof extends in an axial direction of the chemical liquid supply pipe 110. At least one external electrode 320 may be formed, and in some embodiments, at least two external electrodes 320 may be formed. Therefore, the external electrode 320 may generate an electric field outside the chemical liquid supply pipe 110 that is longer (in the axial direction of the chemical liquid supply pipe 110) than an electric field generated by the external electrode 120 according to the exemplary embodiment of FIG. 1. Therefore, the chemical liquid supply apparatus may apply the electric field generated by the external electrode 320 to the chemical liquid for a longer period of time, thereby more effectively reducing static electricity. When at least two external electrodes 320 are formed, the external electrodes 320 may be spaced the same interval from each other along an outer circumferential surface of the chemical liquid supply pipe 110. For example, the external electrodes 320 may be spaced equidistant from one another on the outside surface of the chemical liquid supply pipe 110. One or both of the external electrodes 320 may be electrically connected to the power supply module 130.

Next, a chemical liquid supply apparatus according to an exemplary embodiment of the inventive concept will be described.

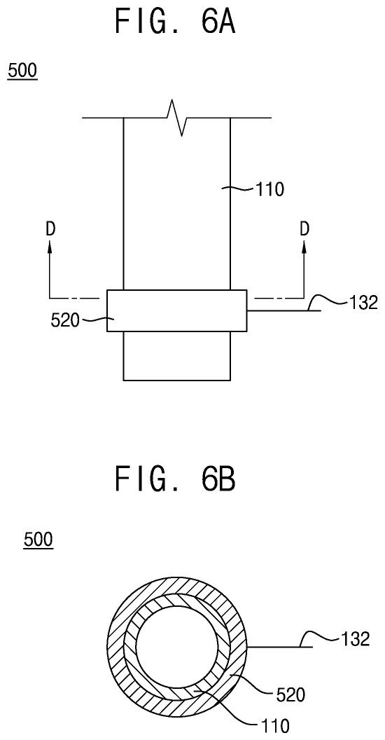

FIG. 5A is a partial vertical sectional view illustrating a chemical liquid supply pipe and an external electrode according to an exemplary embodiment of the inventive concept. FIG. 5B is a horizontal sectional view taken along line C-C of FIG. 5A.

Referring to FIGS. 1, 5A, and 5B, a chemical liquid supply apparatus 400 according to the exemplary embodiment of the inventive concept includes a chemical liquid supply pipe 110, an external electrode 420, and a power supply module 130, including power line 132.

The external electrode 420 may be formed such that a length thereof is less than or equal to a width thereof. At least two external electrodes 420 are spaced apart from each other in an axial direction of the chemical liquid supply pipe 110. Accordingly, at least two external electrodes 420 may be spaced apart from each other within a certain length range in the axial direction of the chemical liquid supply pipe 110. In addition, a plurality of external electrodes 420 may be spaced apart from each other in a circumferential direction of the chemical liquid supply pipe 110. For example, sets of the external electrodes 420 may be spaced equidistant from one another on the outside surface of the chemical liquid supply pipe 110.

The chemical liquid supply apparatus 400 may apply an electric field generated by the external electrode 420 to a chemical liquid flowing in the chemical liquid supply pipe 110 for a longer period of time, thereby more effectively reducing static electricity. In addition, when the chemical liquid flows in the chemical liquid supply pipe 110, the chemical liquid supply apparatus 400 may apply the electric field to the chemical liquid at certain intervals to reduce or remove static electricity. For example, the chemical liquid may irregularly cause static electricity due to friction with an inner circumferential surface of the chemical liquid supply pipe 110, and thus, the static electricity may be more effectively reduced or removed by applying an electric field in a pulse form.

Next, a chemical liquid supply apparatus according to an exemplary embodiment of the inventive concept will be described.

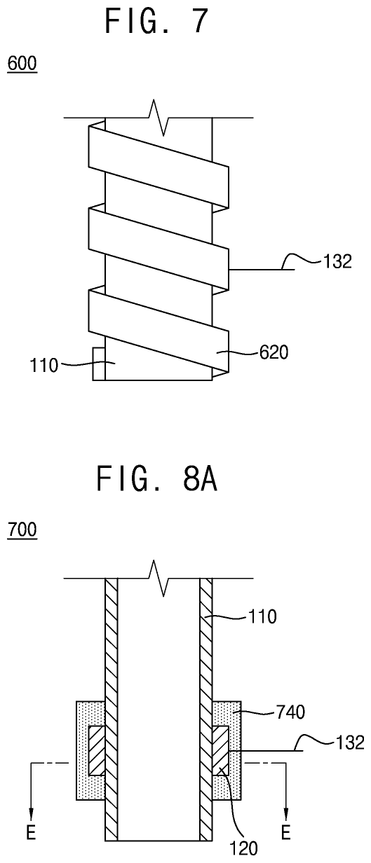

FIG. 6A is a lateral view illustrating a chemical liquid supply pipe and an external electrode according to an exemplary embodiment of the inventive concept. FIG. 6B is a horizontal sectional view taken along line D-D of FIG. 6A.

Referring to FIGS. 1, 6A, and 6B, a chemical liquid supply apparatus 500 according to the exemplary embodiment of the inventive concept includes a chemical liquid supply pipe 110, an external electrode 520, and a power supply module 130, including power line 132.

The external electrode 520 may be formed in a ring shape and may have an inner diameter thereof greater than or equal to an outer diameter of the chemical liquid supply pipe 110. The external electrode 520 is disposed to surround an outer circumferential surface of the chemical liquid supply pipe 110. The external electrode 520 may be formed to have an appropriate length (in the axial direction of the chemical liquid supply pipe 110) according to a level of static electricity generated in a chemical liquid.

Therefore, the chemical liquid supply apparatus 500 may uniformly generate an electric field along the outer circumferential surface of the chemical liquid supply pipe 110 using the external electrode 520, thereby more effectively reducing or removing the static electricity generated in the chemical liquid flowing in the chemical liquid supply pipe 110.

Next, a chemical liquid supply apparatus according to an exemplary embodiment of the inventive concept will be described.

FIG. 7 is a lateral view illustrating a chemical liquid supply pipe and an external electrode according to an exemplary embodiment of the inventive concept.

Referring to FIGS. 1 and 7, a chemical liquid supply apparatus 600 according to the exemplary embodiment of the inventive concept includes a chemical liquid supply pipe 110, an external electrode 620, and a power supply module 130, including power line 132.

The external electrode 620 may be formed in a bar or band shape having a certain length. The external electrode may be spirally formed on an outer circumferential surface of the chemical liquid supply pipe 110. The external electrode 620 may be formed to have a length which is at least greater than a length of the perimeter of the chemical liquid supply pipe 110. The external electrode 620 may be at least twice the length of the perimeter of the chemical liquid supply pipe 110. The external electrode 620 may uniformly generate an electric field along the outer circumferential surface of the chemical liquid supply pipe 110. In addition, the external electrode 620 may apply electric charges at regular intervals in an axial direction of the chemical liquid supply pipe 110.

Therefore, the chemical liquid supply apparatus 600 may uniformly apply an electric field in a circumferential direction of the chemical liquid supply pipe 110 using the external electrode and also apply the electric field in the axial direction of the chemical liquid supply pipe 110, thereby more effectively reducing or removing static electricity.

Next, a chemical liquid supply apparatus according to an exemplary embodiment of the inventive concept will be described.

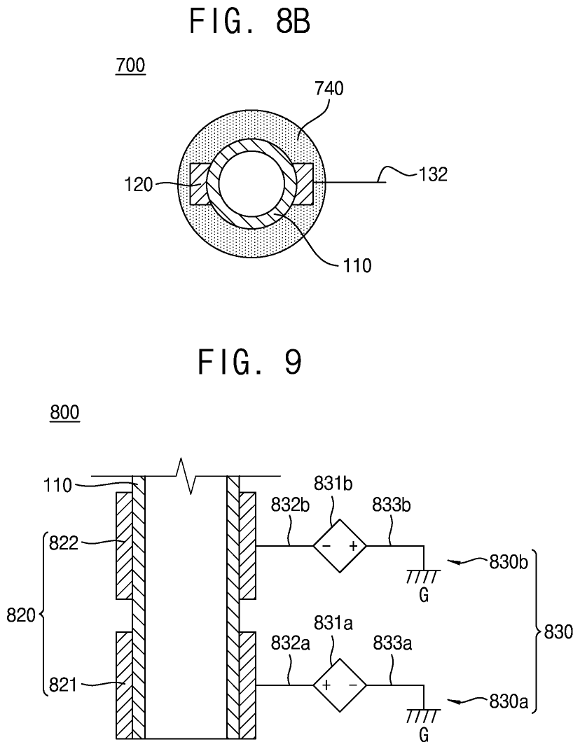

FIG. 8A is a vertical sectional view illustrating a chemical liquid supply pipe, an external electrode, and a protective layer according to an exemplary embodiment of the inventive concept. FIG. 8B is a horizontal sectional view taken along line E-E of FIG. 8A.

Referring to FIGS. 1, 8A, and 8B, a chemical liquid supply apparatus 700 according to the exemplary embodiment of the inventive concept includes a chemical liquid supply pipe 110, an external electrode 120, a power supply module 130 including power line 132, and a protective layer 740.

The protective layer 740 may surround exposed surfaces of the external electrode and may be applied on an outer circumferential surface of the chemical liquid supply pipe 110 to have a certain thickness. A thickness measures a distance from the inner surface of the protective layer 740 (e.g., the surface facing the chemical liquid supply pipe 110) to an outer surface of the protective layer 740. Here, the exposed surfaces mean surfaces, such as an outer surface, an upper surface, and a lower surface of the external electrode, which are exposed to the atmosphere without being in contact with the outer circumferential surface of the chemical liquid supply pipe 110. For example, the exposed surface may refer to every surface of the external electrode 120 except for the surface that faces the outer circumferential surface of the chemical liquid supply pipe 110. The protective layer 740 surrounds the exposed surfaces of the external electrode exposed to the atmosphere and is coupled to the outer circumferential surface of the chemical liquid supply pipe 110. The protective layer 740 may protect the external electrode from an external environment. For example, the protective layer 740 may prevent the external electrode from being damaged by external impacts or corrosive chemicals. Meanwhile, the power supply module 130 may pass through the protective layer 740 and may be electrically connected to the external electrode.

The protective layer 740 may be made of an electrical insulating resin material. For example, the protective layer 740 may be made of any one resin selected from the group consisting of PVDF, PEEK, PFA, and PTFE.

On the other hand, although not shown in detail, the protective layer 740 may also be applied to the chemical liquid supply apparatuses according to other exemplary embodiments in addition to the chemical liquid supply apparatus 100 according to the exemplary embodiment shown in FIGS. 2A and 2B. For example, the protective layer 740 may be formed to surround the external electrode 220 of FIG. 3, the external electrode 320 of FIG. 4A, the external electrode 420 of FIG. 5A, the external electrode 520 of FIG. 6A, or the external electrode 620 of FIG. 7.

Next, a chemical liquid supply apparatus according to an exemplary embodiment of the inventive concept will be described.

FIG. 9 is a schematic configuration view illustrating a chemical liquid supply pipe, an external electrode, and a power supply module according to an exemplary embodiment of the inventive concept.

Referring to FIGS. 1 and 9, a chemical liquid supply apparatus 800 according to the exemplary embodiment of the inventive concept includes a chemical liquid supply pipe 110, an external electrode 820, and a power supply module 830.

The external electrode 820 includes a first external electrode 821 and a second external electrode 822. Each of the first external electrode 821 and the second external electrode 822 may be formed as the external electrode shown in FIGS. 2A and 2B, FIG. 3, or FIGS. 6A and 6B. The first external electrode 821 and the second external electrode 822 may be spaced apart from each other in an axial direction of the chemical liquid supply pipe 110. The first external electrode 821 and the second external electrode 822 may be disposed adjacent to a spray end of the chemical liquid supply pipe 110 so as to be spaced apart from each other. For example, the first external electrode 821 may be disposed adjacent to the spray end of the chemical liquid supply pipe 110, and the second external electrode 822 may be spaced apart from the first external electrode 821.

The power supply module 830 may include a first power module 830a and a second power module 830b. Each of the first power module 830a and the second power module 830b may be identical or similar to the power supply module 130 of FIG. 1. The first power module 830a and the second power module 830b are electrically connected to the first external electrode 821 and the second external electrode 822, respectively. In addition, the first power module 830a and the second power module 830b may apply powers having opposite polarities to the first external electrode 821 and the second external electrode 822.

The first power module 830a may include a first power source 831a, a first power source line 832a, and a first ground line 833a. The first power module 830a may be electrically connected to the first external electrode 821 and may apply positive power to the first external electrode 821. The first power source line 832a electrically connects the first power source 831a and the first external electrode 821. The first ground line 833a connects the first power source 831a to a ground.

The second power module 830b may include a second power source 831b, a second power source line 832b, and a second ground line 833b. The second power module 830b may be electrically connected to the second external electrode 822 and may apply negative power to the second external electrode 822. The second power source line 832b electrically connects the second power source 831b and the second external electrode 822. The second ground line 833b connects the second power source 831b to the ground.

The chemical liquid supply apparatus 800 sequentially supplies positive charges and negative charges to the external electrode 820 disposed outside the chemical liquid supply pipe 110. Therefore, the chemical liquid supply apparatus 800 may more efficiently remove static electricity generated in a chemical liquid flowing in the chemical liquid supply pipe 110.

Next, a chemical liquid supply apparatus according to an exemplary embodiment of the inventive concept will be described.

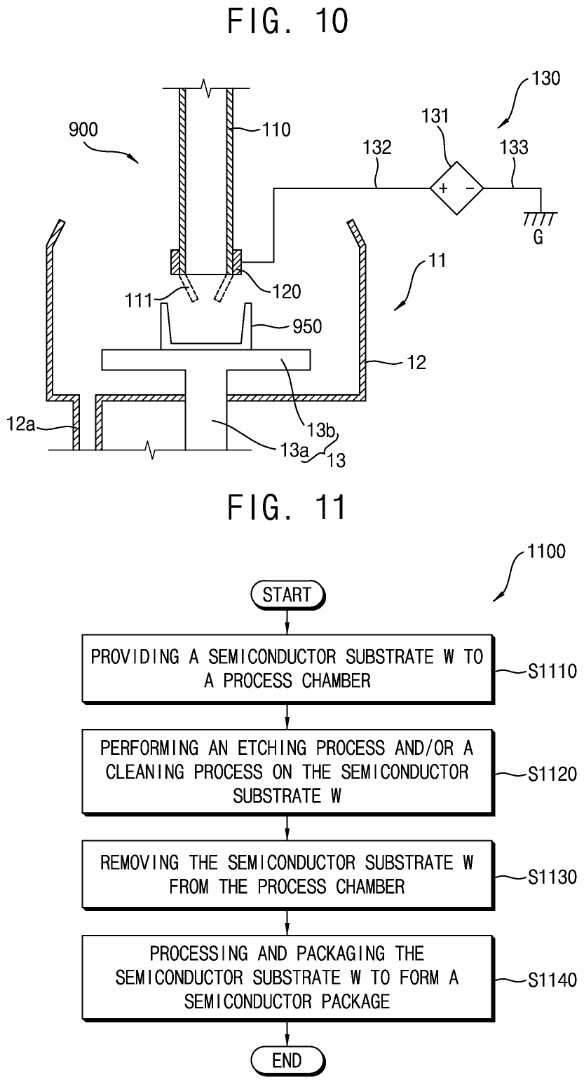

FIG. 10 is a schematic configuration view illustrating a chemical liquid supply apparatus and a semiconductor processing apparatus including the same according to an exemplary embodiment of the inventive concept.

Referring to FIG. 10, a chemical liquid supply apparatus 900 according to the exemplary embodiment of the inventive concept includes a chemical liquid supply pipe 110, an external electrode 120, a power supply module 130, and a charge measurement module 950.

The chemical liquid supply apparatus 900 may adjust a magnitude of power supplied from the power supply module 130 according to an amount of static electrification of a chemical liquid supplied from the chemical liquid supply pipe 110. For example, when the amount of the static electrification of the chemical liquid supplied from the chemical liquid supply pipe 110 is large, a level of a voltage supplied from the power supply module 130 may become higher, thereby reducing the amount of the static electrification of the chemical liquid. Conversely, when the amount of the static electrification of the chemical liquid supplied from the chemical liquid supply pipe 110 is small, a level of a voltage supplied from the power supply module 130 may be lower. Therefore, the chemical liquid supply apparatus 900 may control the static electricity generated in the chemical liquid based on a measurement result.

The charge measurement module 950 may be formed as a Faraday cup assembly (or a Faraday cage assembly) used to measure a charge amount indicating the amount of the static electrification of the chemical liquid. The Faraday cup may be formed to have a general configuration for measuring a charge amount. For example, the Faraday cup assembly may include a Faraday cup for measuring the number of ions of the chemical liquid, a cover for covering an outer side of the Faraday cup, and a plurality of Faraday cables connected to the Faraday cup. The charge measurement module 950 may be disposed below the chemical liquid supply pipe 110 and may measure a charge amount of the chemical liquid sprayed from the chemical liquid supply pipe 110. The charge measurement module 950 may be manually moved into a process chamber when measurement is performed. In addition, the charge measurement module 950 may be moved into the process chamber by a separate moving device (not shown). The charge measurement module 950 measures the charge amount of the chemical liquid supplied from the chemical liquid supply pipe 110 before a semiconductor process starts.

In addition, the charge measurement module 950 may be a non-contact electrostatic measurement sensor. For example, the charge measurement module 950 may be a voltage meter, a surface potentiometer, a charge meter, or an electrostatic discharge detector. Furthermore, the charge measurement module 950 may be an electrostatic voltmeter or a charged plate monitor (CPM). The non-contact electrostatic measurement sensor may measure a level of static electricity of the chemical liquid at a position spaced a certain distance from the chemical liquid supplied from the chemical liquid supply pipe 110.

FIG. 11 is a flow chart illustrating a method of manufacturing semiconductor devices in a semiconductor manufacturing process, according to certain exemplary embodiments. The semiconductor devices may be formed on a semiconductor substrate, such as semiconductor substrate W of the disclosed embodiments.

Referring to FIG. 11, the manufacturing method 1100 includes steps of providing a semiconductor substrate W to a process chamber (S1110), performing an etching process and/or a cleaning process on the semiconductor substrate W (S1120), removing the semiconductor substrate W from the process chamber (S1130), and processing and packaging the semiconductor substrate W to form a semiconductor package (S1140).

For example, referring to the embodiment of FIG. 1, the process may include providing a semiconductor substrate W on a spin chuck 13 in a process chamber 11, and discharging a chemical liquid on a surface of the semiconductor substrate W while the spin chuck 13 rotates to perform an etching or cleaning process. The etching or cleaning process can be part of a series of processes that include forming layers on the semiconductor substrate W, etching or patterning the layers, cleaning, and performing other processes to form or process materials on the semiconductor substrate W. The chemical liquid may be supplied from the chemical liquid storage tank 140 by the chemical liquid supply pump 150 to the surface of the semiconductor substrate W through the chemical liquid supply pipe 110. The external electrode 120, which is provided adjacent to an outer circumferential surface of the chemical liquid supply pipe 110, may generate an electric field that is applied to the chemical liquid as it flows through the chemical liquid supply pipe 110.

Processing and packaging the semiconductor chips may include dicing (or separating) the semiconductor devices on the semiconductor substrate W to obtain individual semiconductor chips, mounting one or more semiconductor chips onto a semiconductor package substrate, and encasing the mounted semiconductor chips with, e.g., a molding. A semiconductor package may be embodied in an electronic device, and may include a stack of semiconductor chips. In some embodiments, the semiconductor package may be embodied as a volatile or non-volatile memory. An electronic device, as used herein, may refer to the to these semiconductor devices or integrated circuit devices, and may additionally include products that include these devices, such as a memory module, memory card, hard drive including additional components, or a mobile phone, laptop, tablet, desktop, camera, or other consumer electronic device, etc.

According to the exemplary embodiments of the inventive concept, since a level of static electricity of a chemical liquid supplied through a chemical liquid supply pipe is controlled outside the chemical liquid supply pipe, it does not cause problems such as corrosion and danger to maintenance of an electrode, which is caused by direct contact with the chemical liquid.

In addition, according to the exemplary embodiments of the inventive concept, it is possible to reduce an arcing phenomenon or other sudden charge transfer phenomena and reduce adsorption of particles onto a semiconductor substrate according to static electricity charged in a chemical liquid, thereby increasing yield of a semiconductor process.

While the embodiments of the inventive concept have been described with reference to the accompanying drawings, it should be understood by those skilled in the art that various modifications may be made without departing from the scope of the inventive concept and without changing essential features thereof. Therefore, the above-described embodiments should be considered in a descriptive sense only and not for purposes of limitation.

What is claimed is:

1. A chemical liquid supply apparatus which supplies a chemical liquid to a process chamber in which a semiconductor manufacturing process is performed, the chemical liquid supply apparatus comprising:
a chemical liquid supply pipe in which the chemical liquid flows, the chemical liquid supply pipe including a spray end, through which the chemical liquid is sprayed, configured to extend into the process chamber;
an external electrode disposed adjacent to an outer circumferential surface of the chemical liquid supply pipe; and
a power supply module configured to apply power to the external electrode.

2. The chemical liquid supply apparatus of claim 1, further comprising:
a chemical liquid storage tank configured to store the chemical liquid; and
a chemical liquid supply pump disposed between the chemical liquid storage tank and the chemical liquid supply pipe.

3. The chemical liquid supply apparatus of claim 1, wherein the chemical liquid supply pipe is made of an electrically insulating material.

4. The chemical liquid supply apparatus of claim 1, wherein the external electrode is in contact with or spaced apart from the outer circumferential surface of the chemical liquid supply pipe.

5. The chemical liquid supply apparatus of claim 1, wherein the external electrode comprises at least two external electrodes, each of the at least two external electrodes having a width less than half of a length of a perimeter of the chemical liquid supply pipe and being spaced apart from each other in a circumferential direction on the outer circumferential surface of the chemical liquid supply pipe.

6. The chemical liquid supply apparatus of claim 5, wherein each of the at least two external electrodes is formed such that a length thereof is less than or equal to a width thereof.

7. The chemical liquid supply apparatus of claim 5, wherein each of the at least two external electrodes is formed such that a length thereof is greater than a width thereof, and the at least two external electrodes are spaced apart from each other in an axial direction of the chemical liquid supply pipe.

8. The chemical liquid supply apparatus of claim 5, wherein each of the at least two external electrodes is formed such that a length thereof is greater than a width thereof.

9. The chemical liquid supply apparatus of claim 5, wherein the at least two external electrodes are disposed symmetrically with respect to a central axis of the chemical liquid supply pipe.

10. The chemical liquid supply apparatus of claim 1, wherein the external electrode is formed in a ring shape having an inner diameter greater than or equal to an outer diameter of the chemical liquid supply pipe.

11. The chemical liquid supply apparatus of claim 1, wherein the external electrode is formed in a band shape or a bar shape and is spirally disposed along the outer circumferential surface of the chemical liquid supply pipe.

12. The chemical liquid supply apparatus of claim 1, wherein the external electrode is disposed such that a lower end thereof is aligned with a spray end of the chemical liquid supply pipe.

13. The chemical liquid supply apparatus of claim 1, further comprising a protective layer made of an electrically insulating resin material, the protective layer being applied on the outer circumferential surface of the chemical liquid supply pipe to have a certain thickness so as to surround exposed surfaces of the external electrode.

14. The chemical liquid supply apparatus of claim 1,
wherein the external electrode comprises a first external electrode and a second external electrode which are spaced apart from each other on the outer circumferential surface of the chemical liquid supply pipe,
wherein the power supply module comprises a first power module configured to supply power to the first external electrode and a second power module configured to supply power to the second external electrode, and
wherein the first power module applies power having a polarity opposite to that of the second power module.

15. The chemical liquid supply apparatus of claim 1, further comprising a charge measurement module configured to measure a charge amount of the chemical liquid sprayed from the chemical liquid supply pipe.

16. A chemical liquid supply apparatus comprising:
a chemical liquid supply pipe comprised of an electrically insulating material and configured to allow a chemical liquid to flow; and
an external electrode configured to generate an electric field outside the chemical liquid supply pipe,
wherein the electric field generated by the external electrode is applied to the chemical liquid to reduce static electricity caused by friction between the chemical liquid and an inner circumferential surface of the chemical liquid supply pipe.

17. The chemical liquid supply apparatus of claim 16, further comprising a power supply module configured to apply positive power or negative power to the external electrode.

18. The chemical liquid supply apparatus of claim 16, further comprising a charge measurement module configured to measure a charge amount of the chemical liquid sprayed from the chemical liquid supply pipe.

19. The chemical liquid supply apparatus of claim 16,
wherein the external electrode comprises at least two external electrodes, each of the at least two external electrodes having a width less than half of a length of a perimeter of the chemical liquid supply pipe and being spaced apart from each other in a circumferential direction on an outer circumferential surface of the chemical liquid supply pipe, and
wherein one of the at least two external electrodes is disposed such that a lower end thereof is aligned with a spray end of the chemical liquid supply pipe.

20. A semiconductor processing apparatus comprising:
a process chamber comprising a chamber housing with a box shape having an open upper portion and an inner space and a spin chuck having a spin shaft protruding from a bottom surface of the chamber housing and a spin plate connected to the spin shaft and having an upper surface on which a semiconductor substrate is mounted;
a chemical liquid storage tank configured to store a chemical liquid;
a chemical liquid supply pump connected to the chemical liquid storage tank;
a chemical liquid supply pipe connected to the chemical liquid supply pump in which the chemical liquid flows, the chemical liquid supply pipe including a spray end, through which the chemical liquid is sprayed, configured to extend to be disposed above the spin plate of the process chamber;
an external electrode disposed adjacent to an outer circumferential surface of the chemical liquid supply pipe to be adjacent to the spray end; and
a power supply module configured to apply power to the external electrode.
